(19) United States
(12) Patent Application Publication
(10) Pub. No.: US 2025/0224683 A1
(43) Pub. Date: Jul. 10, 2025

(54) SUBSTRATE PROCESSING METHOD AND SUBSTRATE PROCESSING SYSTEM

(71) Applicant: Tokyo Electron Limited, Tokyo (JP)

(72) Inventors: Sho KUMAKURA, Miyagi (JP); Kenta ONO, Miyagi (JP); Yuta NAKANE, Miyagi (JP); Tetsuya NISHIZUKA, Miyagi (JP); Masanobu HONDA, Miyagi (JP)

(73) Assignee: Tokyo Electron Limited, Tokyo (JP)

(21) Appl. No.: 19/090,559

(22) Filed: Mar. 26, 2025

Related U.S. Application Data
(63) Continuation of application No. PCT/JP2023/033670, filed on Sep. 15, 2023.

(30) Foreign Application Priority Data
Sep. 27, 2022 (JP) 2022-153334

(51) Int. Cl. G03F 7/40; G03F 7/30; G03F 7/36; G03F 7/38

(52) U.S. Cl. CPC G03F 7/40; G03F 7/30; G03F 7/36; G03F 7/38

(57) ABSTRACT

A substrate processing method includes: (a) performing wet development on a metal-containing resist of a substrate; and (b) performing dry development on the metal-containing resist, wherein the metal-containing resist includes an exposed first region and an unexposed second region, wherein in (a), one of the first region and the second region is partially removed in a thickness direction of the one of the first region and the second region, and wherein in (b), a remaining portion of the one of the first region and the second region is removed.

### CROSS-REFERENCE TO RELATED APPLICATIONS

The application is a Bypass Continuation Application of PCT International Application No. PCT/JP2023/033670, filed on Sep. 15, 2023 and designating the United States, the international application being based upon and claiming the benefit of priority from Japanese Patent Application No. 2022-153334, filed on Sep. 27, 2022, the entire content of each are incorporated herein by reference.

### TECHNICAL FIELD

The present disclosure relates to a substrate processing method and a substrate processing system.

### BACKGROUND

Extreme ultraviolet (EUV) light is used for exposure of a photoresist. Patent Document 1 discloses a metal-containing resist as a photoresist exposed to EUV light, and dry development and wet development as development thereof.

### PRIOR ART DOCUMENT

### Patent Document

Patent Document 1: Japanese Patent Laid-Open Publication No. 2021-52343

### SUMMARY

Some embodiments of the present disclosure provide a substrate processing method. The substrate processing method includes: (a) performing wet development on a metal-containing resist of a substrate; and (b) performing dry development on the metal-containing resist. The metal-containing resist includes an exposed first region and an unexposed second region. In (a), one of the first region and the second region is partially removed in a thickness direction of the one of the first region and the second region. In (b), a remaining portion of the one of the first region and the second region is removed.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart of a substrate processing method according to an exemplary embodiment.

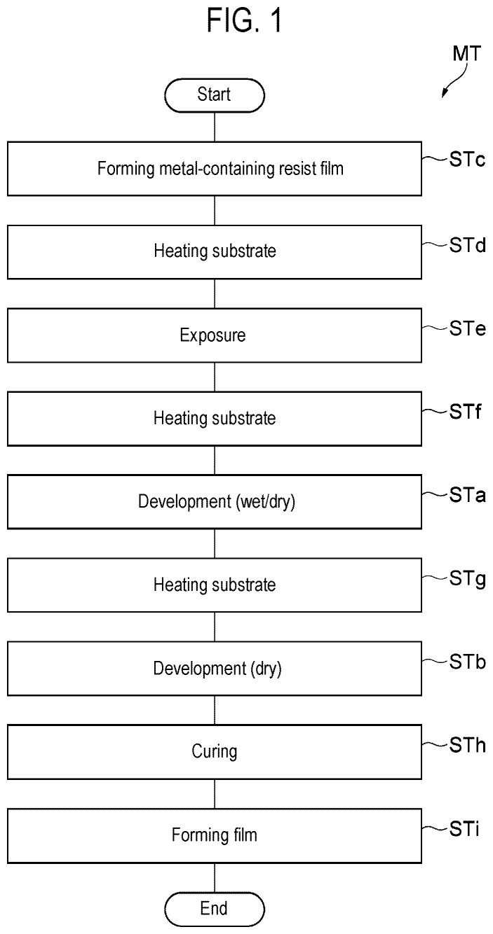

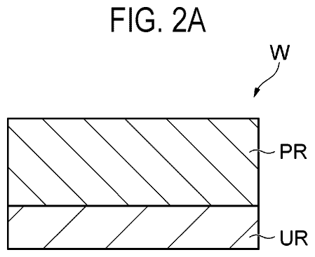

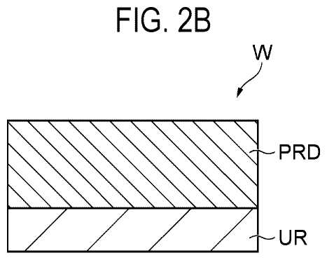

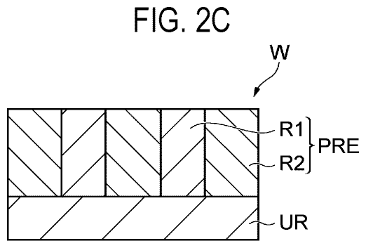

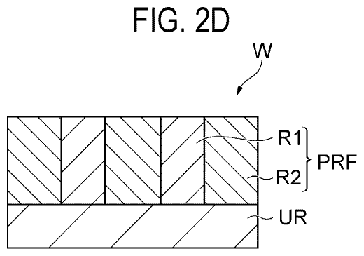

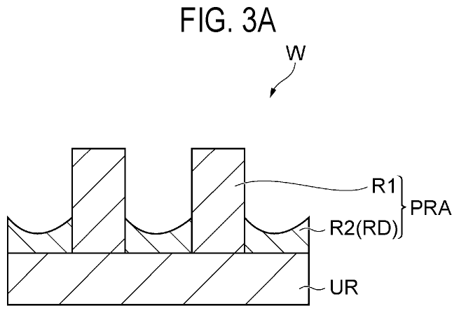

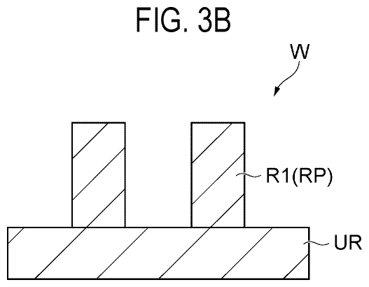

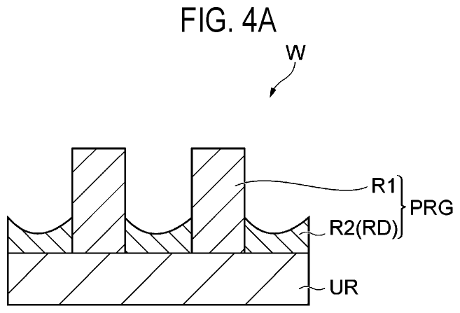

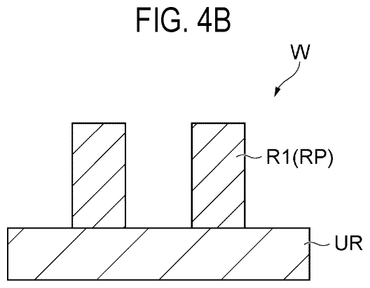

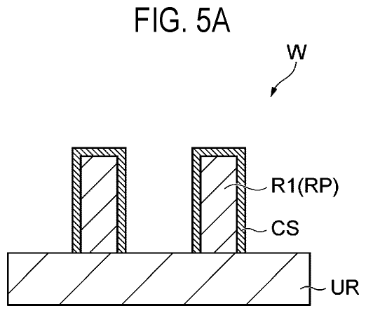

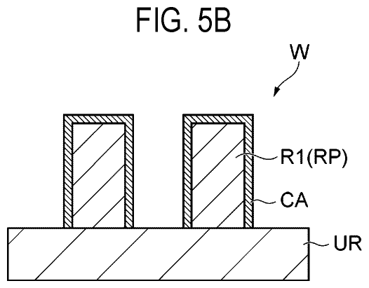

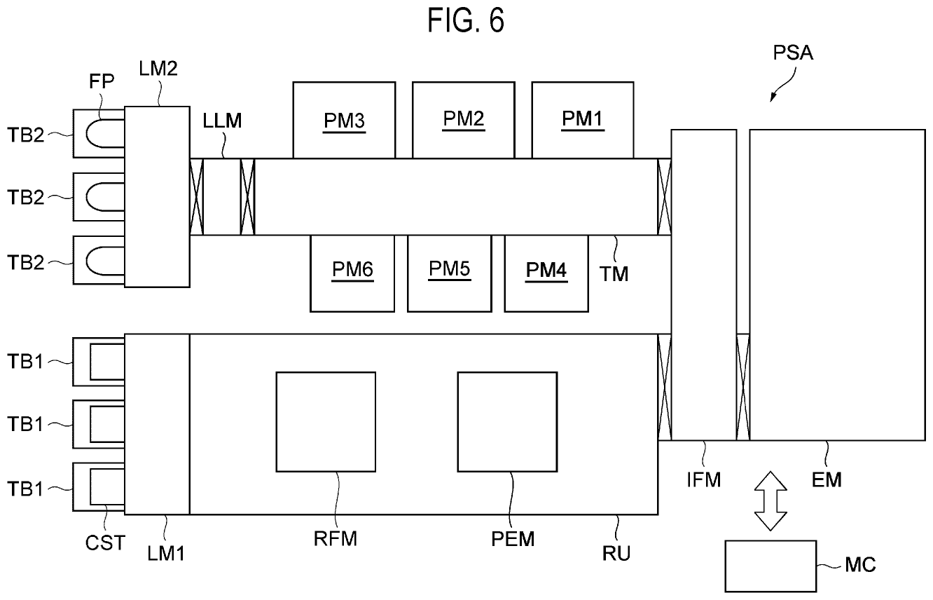

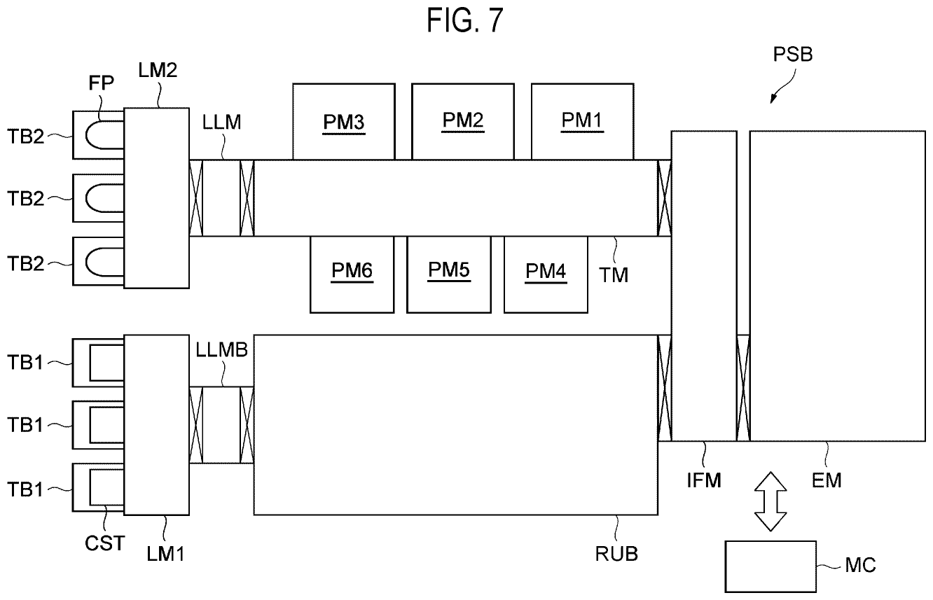

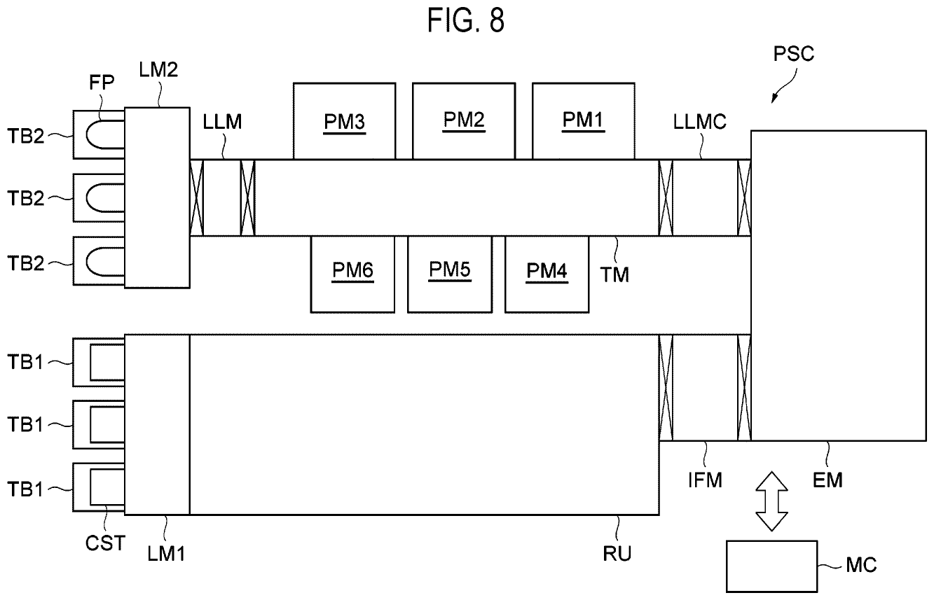

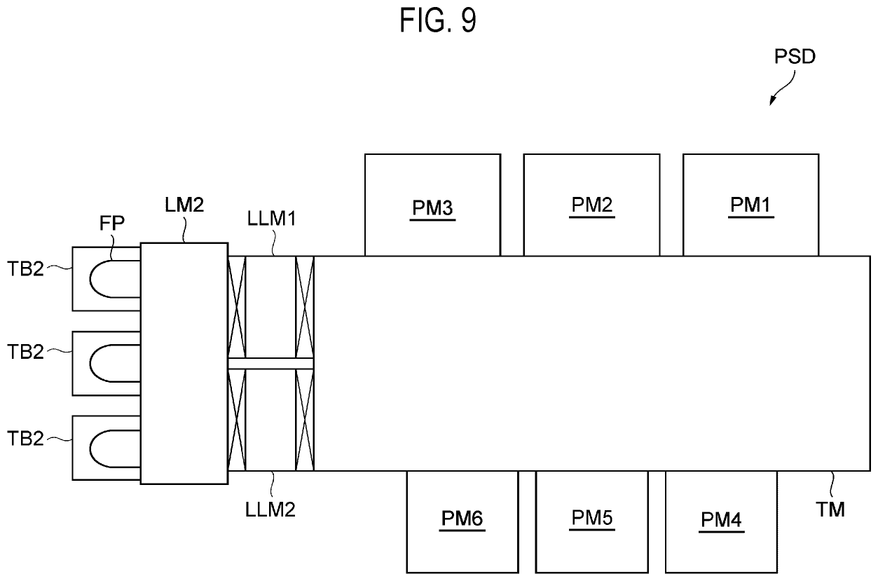

Each of FIGS. 2A to 2D is a partially enlarged cross-sectional view of an example of a substrate to which a corresponding step of the substrate processing method shown in FIG. 1 is applied.

Each of FIG. 3A and FIG. 3B is a partially enlarged cross-sectional view of an example of a substrate to which a corresponding step of the substrate processing method shown in FIG. 1 is applied.

Each of FIG. 4A and FIG. 4B is a partially enlarged cross-sectional view of an example of a substrate to which a corresponding step of the substrate processing method shown in FIG. 1 is applied.

Each of FIG. 5A and FIG. 5B is a partially enlarged cross-sectional view of an example of a substrate to which a corresponding step of the substrate processing method shown in FIG. 1 is applied.

FIG. 6 is a diagram showing a substrate processing system according to an exemplary embodiment.

FIG. 7 is a diagram showing a substrate processing system according to another exemplary embodiment.

FIG. 8 is a diagram showing a substrate processing system according to another exemplary embodiment.

FIG. 9 is a diagram showing a substrate processing system according to another exemplary embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Various exemplary embodiments will now be described in detail with reference to the drawings, in which the same or corresponding parts are designated by the same reference numerals.

FIG. 1 is a flowchart showing a substrate processing method according to an exemplary embodiment. Each of FIGS. 2A to 2D, FIGS. 3A and 3B, FIGS. 4A and 4B, and FIGS. 5A and 5B is a partially enlarged cross-sectional view of an example of a substrate to which a corresponding step of the substrate processing method shown in FIG. 1 is applied. The substrate processing method shown in FIG. 1 (hereinafter, referred to as “method MT”) includes step STa and step STb. The method MT may further include one or more steps among steps STc to STi.

In step STc, a resist film PR is formed on an underlying region UR and a substrate W shown in FIG. 2A is obtained. The underlying region UR includes one or more films to which a pattern of a mask formed of the resist film PR is transferred. The resist film PR is a metal-containing resist film to be exposed by extreme ultraviolet (EUV) light. The resist film PR includes a metal such as tin (Sn). The resist film PR may be formed by a dry process such as atomic layer deposition (ALD), chemical vapor deposition (CVD), or physical vapor deposition (PVD), or may be formed by a wet process such as spin coating.

In one embodiment, step STd may be performed after step STc. In step STd, the substrate W is heated. That is, in step STd, a baking process for the resist film PR is performed. The baking process in step STd is also called a pre-bake (post apply bake: PAB). Heating the substrate W may be performed by at least one heating mechanism such as a heater in a substrate support that supports the substrate W, a lamp heater, or the like. In step STd, the substrate W may be heated in atmospheric atmosphere or an inert atmosphere. In step STd, the substrate W may be heated to 50 degrees C. or more and 250 degrees C. or less, or may be heated to 50 degrees C. or more and 200 degrees C. or less. In step STd, by heating the substrate W, a substrate W having a cured resist film PRD as shown in FIG. 2B is obtained.

Subsequently, step STe is performed. In step STe, the resist film PR or the resist film PRD is exposed. In step STe, a mask (reticle) for exposure is placed on the substrate W, and the resist film PR or the resist film PRD is irradiated with EUV light via the mask. As a result of step STe, as shown in FIG. 2C, a substrate W having an exposed resist film PRE is obtained. The resist film PRE includes a first region R1 and a second region R2. The first region R1 is an exposed region. The second region R2 is an unexposed region. That is, the second region R2 is a region hidden by the mask in step STe.

In one embodiment, step STf may be performed after step STe. In step STf, the substrate W exposed in step STe is heated. That is, in step STf, the resist film PRE is subjected to a baking process. The baking process in step STe is also called a post exposure bake (PEB). In step STf, the substrate W is heated by using at least one heating mechanism among a heater in a substrate support that supports the substrate W, a lamp heater, and the like. In step STf, the substrate W may be heated under an atmosphere of at least one of the air, nitrogen gas, a rare gas, or oxygen gas. In addition, in step STf, the substrate W may be heated under an atmospheric pressure environment or a depressurized environment. In step STf, the substrate W may be heated to a first temperature. The first temperature may be 150 degrees C. or more and 250 degrees C. or less, 160 degrees C. or more and 240 degrees C. or less, or 170 degrees C. or more and 230 degrees C. or less, and is, for example, 180 degrees C. In step STf, a temperature of the substrate W may be gradually or stepwise increased to a target temperature (e.g., 180 degrees C.). In step STf, by heating the substrate W, a substrate W having a resist film PRF as shown in FIG. 2D is obtained. According to step STf, the resist film PRF having improved film quality with respect to the resist film PRE is obtained, and a selectivity (i.e., contrast) in development described later is improved.

Subsequently, step STa is performed. In step STa, the resist film PRE or the resist film PRF is developed, and one of the first region R1 and the second region R2 is partially removed in a thickness direction thereof. As a result of step STa, as shown in FIG. 3A, a substrate W having a partially developed resist film PRA is obtained. When the second region R2 is removed in step STa, the development is negative development, and when the first region R1 is removed, the development is positive development. Hereinafter, the one of the first region and the second region partially removed in step STa is referred to as a region RD. In the illustrated example, the second region R2 is the region RD, but the first region R1 may be the region RD.

The development in step STa is wet development or dry development. In step STa, when the second region R2 is removed by wet development (in the case of negative development), a solvent in a development liquid may be an aromatic compound (e.g., benzene, xylene, or toluene), an ester (e.g., propylene glycol monomethyl ester acetate, ethyl acetate, ethyl lactate, n-butyl acetate, or butyrolactone), an alcohol (e.g., 4-methyl-2-pentanol, 1-butanol, isopropanol, 1-propanol, or methanol), a ketone (e.g., methyl ethyl ketone, acetone, cyclohexanone, 2-heptanone, or 2-octanone), an ether (e.g., tetrahydrofuran, dioxane, or anisole), or the like.

In step STa, when the first region R1 is removed by wet development (positive development), an aqueous solution of an acid or a base can be used as the development liquid. In this case, the development liquid may be a quaternary ammonium hydroxide composition, such as tetramethylammonium hydroxide, tetraethylammonium hydroxide, tetrapropylammonium hydroxide, tetrabutylammonium hydroxide, or a combination thereof. The quaternary ammonium hydroxide can be represented by a formula R₄NOH, where R is a methyl group, an ethyl group, a propyl group, a butyl group, or a combination thereof.

In the wet development of step STa, an additive may be used together with the development liquid. The additive may be a dissolved salt that includes a cation selected from the group consisting of ammonium, a d-block metal cation (hafnium, zirconium, lanthanum, or the like), a f-block metal cation (cerium, lutetium, or the like), a p-block metal cation (aluminum, tin, or the like), an alkali metal (lithium, sodium, potassium, or the like), and a combination thereof, and an anion selected from the group consisting of fluorine, chlorine, bromine, iodine, nitric acid, sulfuric acid, phosphoric acid, silicic acid, boric acid, peroxide, butoxide, formic acid, oxalic acid, ethylenediamine-tetraacetic acid (EDTA), tungstic acid, molybdic acid, and a combination thereof. As another additive, for example, a molecular chelating agent may be used. The molecular chelating agent may be, for example, polyamine, alcohol amine, amino acid, carboxylic acid, or a combination thereof.

In addition, during a period in which the wet development is performed in step STa, one or more among a type of the development liquid, a concentration of the development liquid (i.e., a dilution degree of the development liquid and the additive), a temperature of the development liquid, a speed of rotation or movement of the substrate support that supports the substrate W, and an acceleration of rotation or movement of the substrate support may be changed. For example, in step STa, a development liquid having a high solubility of the resist film may be used, and then a development liquid having a low solubility of the resist film may be used. In step STa, a development liquid having a high concentration may be used, and then a development liquid having a low concentration may be used. In step STa, a development liquid having a high temperature (e.g., 30 degrees C. or higher and 90 degrees C. or lower) may be used, and then a development liquid having a low temperature (e.g., 10 degrees C. or higher and 25 degrees C. or lower) may be used. In step STa, the rotation speed of the substrate support may be set to a low speed (e.g., 50 rpm or higher and 250 rpm or lower) and then changed to a high speed (e.g., 500 rpm or higher and 1,000 rpm or lower).

When dry development is performed in step STa, at least one development gas is supplied to the substrate W. The development gas may include at least one selected from the group consisting of hydrogen bromide (HBr), hydrogen fluoride (HF), hydrogen chloride (HCl), boron trichloride (BCl₃), an organic acid (e.g., a carboxylic acid, or an alcohol), and a β-dicarbonyl compound. The carboxylic acid in the development gas may include, for example, at least one selected from the group consisting of formic acid (HCOOH), acetic acid (CH₃COOH), trichloroacetic acid (CCl₃COOH), monofluoroacetic acid (CFH₂COOH), difluoroacetic acid (CF₂FCOOH), trifluoroacetic acid (CF₃COOH), chloro-difluoroacetic acid (CClF₂COOH), a sulfur-containing acetic acid, thioacetic acid (CH₃COSH), thioglycolic acid (HSCH₂COOH), trifluoroacetic anhydride ((CF₃CO)₂O), and acetic anhydride ((CH₃CO)₂O). The alcohol in the development gas may include, for example, nonafluoro-tert-butyl alcohol ((CF₃)₃COH). The β-dicarbonyl compound in the development gas may be, for example, acetylacetone (CH₃C(O)CH₂C(O)CH₃), trichloroacetylacetone (CCl₃C(O)CH₂C(O)CH₃), hexachloroacetylacetone (CCl₃C(O)CH₂C(O)CCl₃), trifluoroacetylacetone (CF₃C(O)CH₂C(O)CH₃), or hexafluoroacetylacetone (HFAc, CF₃C(O)CH₂C(O)CF₃). In step STa, development may be performed by a thermal reaction between the development gas and the region RD, or development may be performed by a chemical reaction between chemical species of plasma generated from the development gas and the region RD.

During a period in which dry development is performed in step STa, one or more of development parameters including a temperature of the substrate W or the substrate support, a pressure inside a chamber in which development is performed, a flow rate of the development gas, a type of the development gas, and a residence time of the development gas on the substrate W may be changed. In addition, one or more of the development parameters described above may be changed periodically. In one example, in step STa, the temperature of the substrate support may be set to a first temperature (e.g., 10 degrees C. or more and 30 degrees C. or less) and then changed to a second temperature (e.g., 40 degrees C. or more and 100 degrees C. or less).

When dry development is performed in step STa, step STg is performed after step STa. When wet development is performed in step STa, step STg may be performed after step STa.

In step STg, the substrate W is heated. That is, in step STg, the resist film PRA is baked. In step STg, the substrate W is heated by using at least one of heating mechanisms, such as a heater in a substrate support that supports the substrate W, a lamp heater, and the like. In step STg, the substrate W may be heated under an atmosphere of at least one of the air, nitrogen gas, a rare gas, or oxygen gas. In addition, in step STg, the substrate W may be heated under an atmospheric pressure environment or a depressurized environment. In step STg, the substrate W is heated to a temperature higher than the temperature of the substrate W in step STf. In step STg, the substrate W may be heated to a second temperature. The second temperature may be higher than the first temperature. For example, the second temperature may be higher than the first temperature by 5 degrees C. or more, or may be higher by 10 degrees C. or more. In one embodiment, the second temperature may be 170 degrees C. or more and 300 degrees C. or less, 180 degrees C. or more and 280 degrees C. or less, or 190 degrees C. or more and 230 degrees C. or less, and is, for example, 200 degrees C. In step STg, the substrate W may be gradually or stepwise heated to a target temperature (e.g., 200 degrees C.). In step STg, by heating the substrate W, a substrate W having a resist film PRG as shown in FIG. 4A is obtained.

According to step STg, the resist film PRG having a reduced amount of impurities relative to the resist film PRA is obtained. In addition, according to step STg, the resist film PRG having an improved film density or promoted oxidation of compounds relative to the resist film PRA is obtained, and a selectivity (i.e., contrast) in development in step STb described below is improved. In addition, dimensional variation of the resist pattern obtained by the development in step STb, for example, line width variation such as a line width roughness (LWR) or a line edge roughness (LER), is reduced. According to step STg, reaction is promoted in a portion of the resist film PRA where the reaction by exposure is not saturated. As a result, verticality of a side wall surface of the resist pattern after the development in step STb is improved.

Subsequently, step STb is performed. In step STb, dry development is performed on the resist film PRA or the resist film PRG, and a remaining portion of the region RD is removed. In step STb, in addition to the remaining portion of the region RD, a portion of the underlying region UR may be removed. In the dry development of step STb, at least one development gas is supplied to the substrate W. The development gas may include at least one selected from the group consisting of hydrogen bromide (HBr), hydrogen fluoride (HF), hydrogen chloride (HCl), boron trichloride (BCl₃), an organic acid (e.g., a carboxylic acid, or an alcohol), and a β-dicarbonyl compound. The carboxylic acid in the development gas may include at least one selected from the group consisting of formic acid (HCOOH), acetic acid (CH₃COOH), trichloroacetic acid (CCl₃COOH), monofluoroacetic acid (CFH₂COOH), difluoroacetic acid (CF₂FCOOH), trifluoroacetic acid (CF₃COOH), chloro-difluoroacetic acid (CClF₂COOH), a sulfur-containing acetic acid, thioacetic acid (CH₃COSH), thioglycolic acid (HSCH₂COOH), trifluoroacetic anhydride ((CF₃CO)₂O), and acetic anhydride ((CH₃CO)₂O). The alcohol in the development gas may include nonafluoro-tert-butyl alcohol ((CF₃)_{3COH}). The β-dicarbonyl compound in the development gas may be, for example, acetylacetone (CH₃C(O)CH₂C(O)CH₃), trichloroacetylacetone (CCl₃C(O)CH₂C(O)CH₃), hexachloroacetylacetone (CCl₃C(O)CH₂C(O)CCl₃), trifluoroacetylacetone (CF₃C(O)CH₂C(O)CH₃), or hexafluoroacetylacetone (HFAc, CF₃C(O)CH₂C(O)CF₃). In step STb, development may be performed by a thermal reaction between the development gas and the region RD, or development may be performed by a chemical reaction between chemical species of plasma generated from the development gas and the region RD development.

In addition, as in step STa, during a period in which dry development is performed in step STb, one or more of development parameters including a temperature of the substrate W or the substrate support, a pressure inside the chamber in which the development is performed, a flow rate of the development gas, a type of the development gas, and a residence time of the development gas on the substrate W may be changed. In addition, one or more of the development parameters described above may be changed periodically. In one example, in step STb, the temperature of the substrate support may be set to a first temperature (e.g., 10 degrees C. or more and 30 degrees C. or less) and then changed to a second temperature (e.g., 40 degrees C. or more and 100 degrees C. or less).

By step STb, as shown in FIG. 3B or 4B, the remaining portion of the region RD is removed and a substrate W having a resist pattern RP is obtained. The resist pattern RP is formed from the other of the first region R1 and the second region R2. In the illustrated example, the resist pattern RP is formed from the first region R1, but the resist pattern RP may be formed from the second region R2.

In one embodiment, after step STb, step STh and/or step STi may be performed.

In step STh, a curing process is performed on the resist pattern RP to modify a surface of the resist pattern RP as shown in FIG. 5A. As a result, a modified region CS is formed. The modified region CS includes the surface of the resist pattern RP.

In step STh, a gas supply process may be performed. In the gas supply process, the surface of the resist pattern RP is modified by a modification gas supplied to the resist pattern RP. Alternatively, in step STh, a plasma process may be performed. In the plasma process, the surface of the resist pattern RP is modified by plasma formed from the modification gas. The gas used in step STh may include at least one gas selected from the group consisting of a fluorine-containing gas, an oxygen-containing gas, and a rare gas. The fluorine-containing gas may be a fluorocarbon gas and/or a nitrogen trifluoride gas. The oxygen-containing gas may be O₂ gas. In step STh, the substrate W may be further heated.

When the modification gas used in step STh includes a fluorine-containing gas, a metal fluoride is formed in the modified region CS. When the resist pattern RP includes tin, the modified region CS includes non-volatile tin fluoride. The surface of the resist pattern RP is stabilized by the tin fluoride, and the surface of the resist pattern RP is cured.

When the modification gas used in step STh includes oxygen, metal oxide and/or metal hydroxide are formed in the modified region CS. When the resist pattern RP includes tin, the modified region CS includes tin oxide and/or tin hydroxide. The surface of the resist pattern RP is stabilized by the tin oxide and/or tin hydroxide, and the surface of the resist pattern RP is cured.

Alternatively, in step STh, a heating process may be performed. That is, a baking process may be performed on the resist pattern RP. By such a heating process, the surface of the resist pattern RP is modified to form the modified region CS.

Alternatively, in step STh, the resist pattern RP may be irradiated with electron beams, laser light, or electromagnetic waves. In this case, impurities are removed from the modified region CS, and a crosslinking reaction between tin and oxygen is induced. As a result, a film density of the resist pattern RP is improved in the modified region CS to stabilize the surface of the resist pattern RP, and the surface of the resist pattern RP is cured.

According to step STh, erosion and/or corrosion of the resist pattern RP is suppressed. In addition, collapse of the resist pattern RP is suppressed. In addition, a pattern width of the resist pattern RP can be reduced. In addition, dimensional variations of the resist pattern RP, for example, a line width variations such as LWR and LER, are reduced. In addition, a resistance of the resist pattern RP with respect to etching the underlying region UR that may be performed later is increased.

In step STi, as shown in FIG. 5B, a film CA is formed to cover the surface of the resist pattern RP. The film CA may be a silicon-containing film, a carbon-containing film, or a tin oxide film. The silicon-containing film may be a silicon oxide film or a silicon film. The film CA is formed by chemical vapor deposition (CVD) (thermal CVD or plasma CVD), atomic layer deposition (ALD), or physical vapor deposition (PVD). In an ALD method, a cycle including a first step of depositing a precursor on the surface of the substrate W by using a first gas (precursor gas), a second step of purging a chamber, a third step of modifying the precursor by using a second gas (reaction gas), and a fourth step of purging the chamber is repeated. The ALD in step STi may be thermal ALD. In the third step of the thermal ALD, a reaction between the precursor and the second gas is promoted by heating. Alternatively, the ALD in step STi may be plasma ALD. In the third step of the plasma ALD, plasma of the second gas is generated, and active species of the plasma are supplied to the precursor.

When the film CA is a silicon oxide film, the film CA can be formed by thermal CVD or plasma CVD by using a gas mixture including a silicon-containing gas and an oxygen-containing gas. Alternatively, when the film CA is a silicon oxide film, the film CA can be formed by thermal ALD or plasma ALD by using a silicon-containing gas as the first gas and an oxygen-containing gas as the second gas. The silicon-containing gas is, for example, a halogenated silicon gas such as SiF₄ gas or SiCl₄ gas, aminosilane gas, or the like. The oxygen-containing gas is, for example, O₂ gas, O₃ gas, CO gas, CO₂ gas, or the like.

When the film CA is a carbon-containing film, the film CA can be formed by plasma CVD by using a hydrocarbon gas such as CH₄ gas, C₂H₄ gas, or the like. Alternatively, when the film CA is a carbon-containing film, the film CA can be formed by thermal CVD or thermal ALD by using a first gas including isocyanate, carboxylic acid, or carboxylic acid halide, and a second gas having amine or a hydroxyl group. Alternatively, when the film CA is a carbon-containing film, the film CA can be formed by thermal CVD or thermal ALD by using a first gas including carboxylic acid anhydride and a second gas having amine. Alternatively, when the film CA is a carbon-containing film, the film CA can be formed by thermal CVD or thermal ALD by using a first gas including bisphenol A and a second gas having diphenyl carbonate or epichlorohydrin. Alternatively, when the film CA is a carbon-containing film, the film CA can be formed by thermal CVD, plasma CVD, thermal ALD, or plasma ALD by using a first gas including epoxide, carboxylic acid, carboxylic acid halide, carboxylic acid anhydride, isocyanate, or phenol, and a second gas having an inorganic compound gas having an NH bond, an inert gas, N₂ and H₂, H₂O, or H₂ and O₂. Alternatively, when the film CA is a carbon-containing film, the film CA can be formed by plasma CVD by using a gas including a fluorocarbon such as CF₄, C₄F₈, C₃F₈, or C₄F₆.

When the film CA is a tin oxide film, the film CA can be formed by thermal CVD, plasma CVD, thermal ALD, or plasma ALD by using a first gas which is a tin-containing gas and a second gas which is an oxygen-containing gas. The first gas includes a stannane compound, an oxygen-containing tin compound, a nitrogen-containing tin compound, or a tin halide compound. Examples of the stannane compound include stannane, tetramethylstannane, tributylstannane, phenyltrimethylstannane, tetravinylstannane, dimethyldichlorostannane, butyltrichlorostannane, trichlorophenylstannane, and the like. Examples of the oxygen-containing tin compound include tributyltin methoxide, tert-butoxide tin, dibutyltin diacetate, triphenyltin acetate, tributyltin oxide, triphenyltin acetate, triphenyltin hydroxide, butylchlorotin dihydroxide, acetylacetonate tin, and the like. Examples of the nitrogen-containing tin compound include dimethylaminotrimethyltin, tris(dimethylamino)tert-butyltin, azidotrimethyltin, tetrakis(dimethylamino)tin, N,N′-di-tert-butyl-2,3-diamidbutanetin(II), and the like. Examples of the tin halide compound include tin chloride, tin bromide, tin iodide, dimethyltin dichloride, butyltin trichloride, phenyltin trichloride, and the like. The second gas includes, for example, H₂O, H₂O₂, O₃, O₂, and the like.

When the film CA is a silicon film, a capacitively coupled plasma processing apparatus may be used to form the film CA. In this case, plasma is generated from an inert gas (e.g., a rare gas or hydrogen gas) in a chamber of the capacitively coupled plasma processing apparatus, and a negative voltage is applied to an upper electrode. This causes ions in the plasma to collide with a ceiling plate of the upper electrode, so that silicon included in the ceiling plate is released from the ceiling plate. The silicon released from the ceiling plate is deposited on the surface of the substrate W placed on a substrate support in the chamber to form the film CA.

According to step STi, erosion and/or corrosion of the resist pattern RP is suppressed. In addition, collapse of the resist pattern RP due to moisture absorption is suppressed. In addition, a pattern width of the resist pattern RP can be increased. In addition, dimensional variations of the resist pattern RP, for example, line width variations such as LWR and LER, are reduced. In addition, a resistance of the resist pattern RP with respect to etching the underlying region UR that may be performed later is improved.

In the method MT, when wet development is performed in step STa, a time required for development becomes shorter than that in dry development. In addition, in the method MT, a portion of the region RD is removed in the thickness direction in step STa, and the remaining portion of the region RD is removed by dry development in step STb. Thus, in the method MT, a bottom of the other of the first region and the second region in which the underlying region UR and the resist pattern RP are formed is not exposed to the development liquid. Therefore, according to the method MT, collapse of the resist pattern RP is suppressed.

A substrate processing system according to several exemplary embodiments will now be described with reference to FIGS. 6 to 9.

A substrate processing system PSA shown in FIG. 6 may be used in the method MT. The substrate processing system PSA includes at least one stage TB1, a loader module LM1, a resist film formation unit RU, an interface module IFM, an exposure module EM, a transfer module TM, process modules PM1 to PM6, a load lock module LLM, a loader module LM2, at least one stage TB2, and a controller MC.

The at least one stage TB1 is disposed along the loader module LM1. A cassette CST is placed on the at least one stage TB1. The cassette CST is configured to accommodate therein the substrate W having the underlying region UR.

The loader module LM1 includes a chamber and a transfer device. An interior of the chamber of the loader module LM1 may be set to atmospheric atmosphere, and a pressure thereof may be set to atmospheric pressure. The transfer device of the loader module LM1 includes a transfer robot. The transfer device of the loader module LM1 is configured to transfer the substrate W in the cassette CST to the resist film formation unit RU.

The resist film formation unit RU includes a resist film formation module RFM and a heating module PEM. The resist film formation module RFM is an apparatus configured to form the resist film PR on the underlying region UR of the substrate W in step STc. The resist film formation module RFM may be an apparatus configured to form the resist film PRF by, for example, a wet process such as spin coating or the like. An interior of the resist film formation unit RU may be set to atmospheric atmosphere, and the pressure thereof may be set to atmospheric pressure.

The heating module PEM is an apparatus configured to heat the substrate W in step STd. That is, the heating module PEM is an apparatus configured to bake the resist film PR in step STd. The heating module PEM includes at least one arbitrary heating mechanism such as a heater in a substrate support that supports the substrate W, a lamp heater, or the like. By the heating module PEM, the substrate W having the cured resist film PRD is produced.

The interface module IFM is disposed between the resist film formation unit RU and the exposure module EM, and is also disposed between the exposure module EM and the transfer module TM. The interface module IFM includes a chamber and a transfer device. The interface module IFM is connected to the resist film formation unit RU via a gate valve, is connected to the exposure module EM via a gate valve, and is also connected to the transfer module TM via a gate valve. The interface module IFM may be configured to manage an atmosphere, a humidity, a temperature, and the like inside the chamber.

The transfer device of the interface module IFM includes a transfer robot. The transfer device of the interface module IFM is configured to transfer the substrate W from the resist film formation unit RU to the exposure module EM and to transfer the substrate W from the exposure module EM to the transfer module TM.

The exposure module EM is an exposure apparatus configured to expose a resist film to EUV light in step STe. By exposing the resist film by the exposure module EM, the substrate W having the exposed resist film PRE is produced.

The transfer module TM includes a chamber and a transfer device. The chamber of the transfer module TM is configured be capable of being depressurized. The transfer device of the transfer module TM includes a transfer robot. The transfer device of the transfer module TM is configured to transfer the substrate W received from the interface module IF. The transfer device of the transfer module TM is configured to transfer the substrate W between any two process modules among the process modules PM1 to PM6, and between any one process module among the process modules PM1 to PM6 and the load lock module LLM.

Each of the process modules PM1 to PM6 includes at least one development module and at least one heating module.

One of the process modules PM1 to PM6 may be a heating module configured to heat the substrate W in step STf. That is, one of the process modules PM1 to PM6 may be a heating module configured to perform the baking process for the resist film PRE in step STf. The heating module used in step STf includes at least one arbitrary heating mechanism, such as a heater in a substrate support that supports the substrate W, a lamp heater, or the like. The heating module used in step STf may further include a chamber and a gas supply. The substrate support may be rotatably provided in the chamber. A rotation speed of the substrate support may be changeable. In addition, the gas supply may be configured to supply at least one of the atmosphere (air), nitrogen gas, a rare gas, or oxygen gas into the chamber. By the heating module used in step STf, the substrate W having the resist film PRF is produced.

One of the process modules PM1 to PM6 is a development module used in development in step STa. By the development module used in step STa, the substrate W having the resist film PRA is produced.

When the development in step STa is wet development, the development module used in step STa is a wet development module configured to perform wet development. The wet development module includes a chamber, a substrate support, and a development liquid supply. The substrate support is configured to support a substrate in the chamber. The substrate support may be rotatable, and a rotation speed thereof may be changeable. In addition, the development liquid supply is configured to supply a development liquid to the substrate W on the substrate support. One or more of a type, concentration, and temperature of the development liquid may be changeable.

When the development in step STa is dry development, the development module used in step STa is a dry development module configured to perform dry development. The dry development module used in step STa includes a chamber, a substrate support, and a gas supply. An interior of the chamber can be depressurized. The substrate support is configured to support the substrate in the chamber. The gas supply is configured to supply a development gas. The dry development module may perform development by a thermal reaction between the development gas and the region RD. Alternatively, the dry development module may perform development by a chemical reaction between chemical species in plasma generated from the development gas and the region RD. In this case, the dry development module includes a plasma generator. The plasma generator may generate plasma from the development gas in the chamber. Alternatively, the chemical species may be supplied to the substrate W in the chamber from the plasma generated from the development gas outside the chamber by the plasma generator.

One of the process modules PM1 to PM6 may be a heating module configured to heat the substrate W in step STg. That is, one of the process modules PM1 to PM6 may be a heating module configured to perform the baking process for the resist film PRA in step STg. The heating module used in step STg includes at least one arbitrary heating mechanism, such as a heater in a substrate support that supports the substrate W, a lamp heater, or the like. The heating module used in step STg may further include a chamber and a gas supply. The substrate support may be rotatably provided in the chamber. A rotation speed of the substrate support may be changeable. In addition, the gas supply may be configured to supply at least one of the atmosphere (air), nitrogen gas, a rare gas, and oxygen gas into the chamber. By the heating module used in step STg, the substrate W having the resist film PRG is produced. The heating module used in step STf and the heating module used in step STg may be a common process module or may be separate process modules.

One of the process modules PM1 to PM6 is a dry development module used in the development in step STb. The dry development module used in step STb is configured to perform dry development. The dry development module used in step STb includes a chamber, a substrate support, and a gas supply. An interior of the chamber can be depressurized. The substrate support is configured to support a substrate in the chamber. The gas supply is configured to supply a development gas. The dry development module may perform development by a thermal reaction between the development gas and the region RD. Alternatively, the dry development module may perform development by a chemical reaction between chemical species in plasma generated from the development gas and the region RD. In this case, the dry development module further includes a plasma generator. The plasma generator may generate plasma from the development gas in the chamber. Alternatively, the chemical species may be supplied to the substrate W in the chamber from the plasma generated from the development gas outside the chamber by the plasma generator. By the dry development module used in step STb, the substrate W having the resist pattern RP is produced.

In one embodiment, the dry development module used in step STb may include a heating mechanism. The heating mechanism may be a dry development module including at least one heating mechanism such as a heater in a substrate support that supports the substrate W, a lamp heater, or the like. The dry development module including the heating mechanism and used in step STb may also be used to heat the substrate W in step STg. In addition, step STa, step STg, and step STb may be performed in the dry development module including the heating mechanism and used in step STb. In addition, step STf, step STa, step STg, and step STb may be performed in the dry development module including the heating mechanism and used in step STb.

One of the process modules PM1 to PM6 may be an apparatus configured to perform the curing process on the resist pattern RP in step STh. By the process module used in step STh, the modified region CS is formed.

The process module used in step STh may be configured to perform the above-mentioned gas supply process. In this case, the process module used in step STh includes a chamber, a substrate support, and a gas supply. An interior of the chamber can be depressurized. The substrate support is configured to support a substrate in the chamber. The gas supply is configured to supply a modification gas into the chamber. The process module used in step STh may further include a heating mechanism for heating the substrate W.

Alternatively, the process module used in step STh may be configured to perform the above-mentioned plasma process. In this case, the process module used in step STh further includes a plasma generator. The plasma generator may generate plasma from the modification gas in the chamber. Alternatively, chemical species may be supplied to the substrate W in the chamber from the plasma generated from the modification gas outside the chamber by the plasma generator.

Alternatively, the process module used in step STh may be a heating module configured to perform the above-mentioned heating process. The heating modules used in two or more of steps STf, STg, and STh may be a common process module. Alternatively, the heating modules used in steps STf, STg, and STh may be separate process modules. When the substrate processing system PSD includes two or more heating modules, the heating modules may be stacked one above another.

One of the process modules PM1 to PM6 is a film-formation module configured to form the film CA in step STi. The film-formation module used in step STi includes a chamber, a substrate support, and a gas supply. An interior of the chamber can be depressurized. The substrate support is configured to support a substrate in the chamber. The gas supply is configured to supply a gas used in step STi into the chamber. The film-formation module used in step STi is configured to form the film CA by thermal CVD, plasma CVD, thermal ALD, or plasma ALD. When the film CA is formed by thermal CVD or thermal ALD, the film-formation module used in step STi further includes a heating mechanism configured to heat the substrate W. When the film CA is formed by plasma CVD or plasma ALD, the film-formation module used in step STi further includes a plasma generator.

The load lock module LLM is disposed between the loader module LM2 and the transfer module TM. The load lock module LLM serves as a preliminary depressurization chamber. The load lock module LLM is connected to the transfer module TM via a gate valve, and is also connected to the loader module LM2 via a gate valve.

The loader module LM2 includes a chamber and a transfer device. An atmosphere inside the chamber of the loader module LM2 may be set to atmospheric atmosphere, and a pressure thereof may be set to atmospheric pressure. The transfer device of the loader module LM2 includes a transfer robot. The transfer device of the loader module LM2 is configured to transfer the substrate W between the load lock module LLM and a cassette FP, which will be described later.

At least one stage TB2 is disposed along the loader module LM2. The cassette FP is placed on the at least one stage TB2. The cassette FP is a container such as a front opening unified pod (FOUP) and is configured to accommodate substrates W therein.

The controller MC may be a computer including a processor, a storage such as a memory or the like, an input device, a display device, a signal input/output interface, and the like. The controller MC is configured to control individual components of the substrate processing system. A control program and recipe data are stored in the storage of the controller MC. The control program is executed by the processor of the controller MC to execute various processes in the substrate processing system. The processor of the controller MC executes the control program and controls individual components of the substrate processing system according to the recipe data, whereby step STa and step STb of the method MT or all steps of the method MT are executed in the substrate processing system.

In one embodiment, the controller MC executes step STa of performing wet development or dry development, and step STb of performing dry development. The controller MC may further execute step STf of heating the exposed substrate W before step STa. In one embodiment, the controller MC may further execute step STg of heating the substrate W between step STa and step STb. In this case, the controller MC may set a temperature of the substrate W in step STg to a temperature higher than a temperature of the substrate W in step STf. The controller MC may further execute one or more other steps of the method MT.

In another embodiment, the controller MC executes step STa of performing dry development, step STg of heating the substrate W, and step STb of performing dry development. The controller MC may further execute step STf of heating the exposed substrate W before step STa. The controller MC may set a temperature of the substrate W in step STg to a temperature higher than the temperature of the substrate W in step STf. The controller MC may further execute one or more other steps of the method MT.

Reference is made to FIG. 7. A substrate processing system PSB shown in FIG. 7 can be used in the method MT. In the following, the substrate processing system PSB will be described in terms of differences between the substrate processing system PSB and the substrate processing system PSA.

The substrate processing system PSB includes a resist film formation unit RUB instead of the resist film formation unit RU. In addition, the substrate processing system PSB further includes a load lock module LLMB. In the substrate processing system PSB, at least one of the process modules PM1 to PM6 is the heating module used in step STg.

The load lock module LLMB is disposed between the loader module LM1 and the resist film formation unit RUB. The load lock module LLMB serves as a preliminary depressurization chamber. The load lock module LLMB is connected to the loader module LM1 via a gate valve, and is also connected to the resist film formation unit RUB via a gate valve.

The resist film formation unit RUB includes a dry development module configured to perform dry development in step STa. The dry development module used in step STa includes a chamber, a substrate support, and a gas supply. An interior of the chamber can be depressurized. The substrate support is configured to support the substrate in the chamber. The gas supply is configured to supply a development gas. The dry development module may perform development by a thermal reaction between the development gas and the region RD. Alternatively, the dry development module may perform development by a chemical reaction between chemical species in plasma generated from the development gas and the region RD. In this case, the dry development module includes a plasma generator. The plasma generator may generate plasma from the development gas in the chamber. Alternatively, chemical species may be supplied to the substrate W in the chamber from the plasma generated from the development gas outside the chamber by the plasma generator.

Reference is made to FIG. 8. A substrate processing system PSC shown in FIG. 8 may be used in the method MT. In the following, the substrate processing system PSC will be described in terms of differences between the substrate processing system PSC and the substrate processing system PSA.

The substrate processing system PSC further includes a load lock module LLMC. In the substrate processing system PSC, the interface module IFM is disposed between the resist film formation unit RU and the exposure module EM. The load lock module LLMC provides a preliminary depressurization chamber, and is disposed between the exposure module EM and the transfer module TM. The load lock module LLMC is connected to the exposure module EM via a gate valve, and is connected to the transfer module TM.

In addition, the substrate processing system PSC may include the resist film formation unit RUB instead of the resist film formation unit RU, like the substrate processing system PSB, and may further include the load lock module LLMB.

Reference is made to FIG. 9. A substrate processing system PSD shown in FIG. 9 may be used in the method MT. In the following, the substrate processing system PSD will be described in terms of differences between the substrate processing system PSD and the substrate processing system PSA.

The substrate processing system PSD does not include the stage TB1, the loader module LM1, the resist film formation unit RU, the interface module IFM, and the exposure module EM. The substrate processing system PSD is configured to apply step STa and step STb to the exposed substrate W accommodated in the cassette FP. The substrate processing system PSD may further perform one or more of step STf, step STg, step STh, and step STi.

The substrate processing system PSD includes load lock modules LLM1 and LLM2, instead of the load lock module LLM. Each of the load lock modules LLM1 and LLM2 provides a preliminary depressurization chamber. Each of the load lock modules LLM1 and LLM2 is disposed between the loader module LM2 and the transfer module TM. Each of the load lock modules LLM1 and LLM2 is connected to the transfer module TM via a gate valve, and is connected to the loader module LM2 via a gate valve. The substrate W is transferred between the loader module LM2 and the transfer module TM via one of the load lock modules LLM1 and LLM2.

Although various exemplary embodiments have been described above, the present disclosure is not limited to the above-described exemplary embodiments, and various additions, omissions, substitutions, and modifications may be made. In addition, elements in different embodiments may be combined to form other embodiments.

For example, steps STa, STg, and STb may be repeated to obtain the resist pattern RP.

Various exemplary embodiments included in the present disclosure will now be described in [E1] to [E22] below.

### [E1]

A substrate processing method, including:
(a) performing wet development on a metal-containing resist of a substrate; and
(b) performing dry development on the metal-containing resist,
wherein the metal-containing resist includes an exposed first region and an unexposed second region,
wherein in (a), one of the first region and the second region is partially removed in a thickness direction of the one of the first region and the second region, and
wherein in (b), a remaining portion of the one of the first region and the second region is removed.

### [E2]

The substrate processing method of [E1], further comprising (c) heating the substrate before (a).

### [E3]

The substrate processing method of [E2], further including (d) heating the substrate between (a) and (b),
wherein a temperature of the substrate in (d) is higher than a temperature of the substrate in (c).

### [E4]

The substrate processing method of [E1], further including (d) heating the substrate between (a) and (b).

### [E5]

The substrate processing method of [E3] or [E4], wherein in (d), the temperature of the substrate is increased gradually or stepwise.

### [E6]

The substrate processing method of any one of [E1] to [E5], further comprising performing a curing process on the other of the first region and the second region after (b).

### [E7]

The substrate processing method of [E6], wherein in the curing process, a gas supply process, a plasma process, a heating process, or an irradiation process of electron beams, laser beams, or electromagnetic waves is performed on the other of the first region and the second region.

### [E8]

The substrate processing method of [E7], wherein in the plasma process, plasma generated from a processing gas, which includes at least one selected from the group consisting of a fluorine-containing gas, an oxygen-containing gas, and a rare gas, is used.

### [E9]

The substrate processing method of any one of [E1] to [E5], wherein after (b), a film is formed to cover a surface of the other of the first region and the second region.

### [E10]

The substrate processing method of [E9], wherein the film is a silicon-containing film, a carbon-containing film, or a tin oxide film.

### [E11]

The substrate processing method of any one of [E1] to [E10], wherein in (b), a gas used to remove the one of the first region and the second region includes at least one selected from the group consisting of hydrogen bromide, hydrogen fluoride, hydrogen chloride, boron trichloride, hydrogen iodide, and an organic acid.

### [E12]

The substrate processing method of any one of [E1] to [E11], wherein in (b), the one of the first region and the second region is removed by at least one of a thermal reaction or a plasma process.

### [E13]

A substrate processing method, including:
(a) performing first dry development on a metal-containing resist of a substrate;
(b) heating the substrate after (a); and
(c) performing second dry development on the metal-containing resist after (b),
wherein the metal-containing resist includes an exposed first region and an unexposed second region,
wherein in (a), one of the first region and the second region is partially removed in a thickness direction of the one of the first region and the second region, and
wherein in (c), a remaining portion of the one of the first region and the second region is removed.

### [E14]

The substrate processing method of [E13], further comprising (d) heating the substrate before (a),
wherein a temperature of the substrate in (b) is higher than a temperature of the substrate in (d).

### [E15]

A substrate processing system, including:
a wet development module configured to perform wet development on a metal-containing resist of a substrate, the metal-containing resist including an exposed first region and an unexposed second region;
a dry development module configured to perform dry development on the metal-containing resist;
a transfer module configured to transfer the substrate to the wet development module and the dry development module; and
a controller,
wherein the controller is configured to control the transfer module, the wet development module, and the dry development module to execute:
   (a) performing the wet development on the metal-containing resist in the wet development module to partially remove one of the first region and the second region in a thickness direction of the one of the first region and the second region; and
   (b) performing dry development on the metal-containing resist in the dry development module to remove a remaining portion of the one of the first region and the second region.

### [E16]

The substrate processing system of [E15], further including a first heating module,
wherein the controller is configured to further execute (c) heating the substrate in the first heating module before (a).

### [E17]

The substrate processing system of [E16], further including a second heating module,
wherein the controller is configured to further execute (d) heating the substrate in the second heating module between (a) and (b), and
wherein a temperature of the substrate in (d) is higher than a temperature of the substrate in (c).

### [E18]

The substrate processing system of [E15], wherein the dry development module includes a heating mechanism configured to heat the substrate,
wherein the controller is configured to further execute:
   (c) heating the substrate by the heating mechanism in the dry development module before (a); and
   (d) heating the substrate by the heating mechanism in the dry development module between (a) and (b), and
wherein a temperature of the substrate in (d) is higher than a temperature of the substrate in (c).

### [E19]

The substrate processing system of [E16], wherein the dry development module includes a heating mechanism configured to heat the substrate,
wherein the controller is configured to further execute (d) heating the substrate by the heating mechanism in the dry development module between (a) and (b), and
wherein a temperature of the substrate in (d) is higher than a temperature of the substrate in (c).

### [E20]

A substrate processing system, including:
a first dry development module configured to perform dry development on a metal-containing resist of a substrate, the metal-containing resist including an exposed first region and an unexposed second region;
a second dry development module configured to perform dry development on the metal-containing resist, and having a heating mechanism configured to heat the substrate;
a transfer module configured to transfer the substrate to the first dry development module and the second dry development module; and
a controller,
wherein the controller is configured to control the transfer module, the first dry development module, and the second dry development module to execute:
   (a) performing dry development on the metal-containing resist in the first dry development module or the second dry development module to partially remove one of the first region and the second region in a thickness direction of the one of the first region and the second region;
   (b) heating the substrate by the heating mechanism in the second dry development module after (a); and
   (c) performing dry development on the metal-containing resist in the second dry development module to remove a remaining portion of the one of the first region and the second region.

### [E21]

The substrate processing system of [E20], wherein (a) includes performing dry development on the metal-containing resist in the second dry development module.

### [E22]

The substrate processing system of [E21], wherein the controller is configured to further execute (d) heating the substrate in the second dry development module before (a), and
wherein a temperature of the substrate in (b) is higher than a temperature of the substrate in (d).

According to the present disclosure in some embodiments, it is possible to suppress collapse of a developed pattern of a metal-containing resist.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method, comprising:
(a) performing wet development on a metal-containing resist of a substrate; and
(b) performing dry development on the metal-containing resist,
wherein the metal-containing resist includes an exposed first region and an unexposed second region,
wherein in (a), one of the first region and the second region is partially removed in a thickness direction of the one of the first region and the second region, and
wherein in (b), a remaining portion of the one of the first region and the second region is removed.

2. The substrate processing method of claim 1, further comprising (c) heating the substrate before (a).

3. The substrate processing method of claim 2, further comprising (d) heating the substrate between (a) and (b),
wherein a temperature of the substrate in (d) is higher than a temperature of the substrate in (c).

4. The substrate processing method of claim 1, further comprising (d) heating the substrate between (a) and (b).

5. The substrate processing method of claim 3, wherein in (d), the temperature of the substrate is increased gradually or stepwise.

6. The substrate processing method of claim 1, further comprising performing a curing process on the other of the first region and the second region after (b).

7. The substrate processing method of claim 6, wherein in the curing process, a gas supply process, a plasma process, a heating process, or an irradiation process of electron beams, laser beams, or electromagnetic waves is performed on the other of the first region and the second region.

8. The substrate processing method of claim 7, wherein in the plasma process, plasma generated from a processing gas, which includes at least one selected from the group consisting of a fluorine-containing gas, an oxygen-containing gas, and a rare gas, is used.

9. The substrate processing method of claim 1, wherein after (b), a film is formed to cover a surface of the other of the first region and the second region.

10. The substrate processing method of claim 9, wherein the film is a silicon-containing film, a carbon-containing film, or a tin oxide film.

11. The substrate processing method of claim 1, wherein in (b), a gas used to remove the one of the first region and the second region includes at least one selected from the group consisting of hydrogen bromide, hydrogen fluoride, hydrogen chloride, boron trichloride, hydrogen iodide, and an organic acid.

12. The substrate processing method of claim 1, wherein in (b), the one of the first region and the second region is removed by at least one of a thermal reaction or a plasma process.

13. A substrate processing method, comprising:
(a) performing first dry development on a metal-containing resist of a substrate;
(b) heating the substrate after (a); and
(c) performing second dry development on the metal-containing resist after (b),
wherein the metal-containing resist includes an exposed first region and an unexposed second region,
wherein in (a), one of the first region and the second region is partially removed in a thickness direction of the one of the first region and the second region, and
wherein in (c), a remaining portion of the one of the first region and the second region is removed.

14. The substrate processing method of claim 13, further comprising (d) heating the substrate before (a),
wherein a temperature of the substrate in (b) is higher than a temperature of the substrate in (d).

15. A substrate processing system, comprising:
a wet development module configured to perform wet development on a metal-containing resist of a substrate, the metal-containing resist including an exposed first region and an unexposed second region;
a dry development module configured to perform dry development on the metal-containing resist;
a transfer module configured to transfer the substrate to the wet development module and the dry development module; and
a controller,
wherein the controller is configured to control the transfer module, the wet development module, and the dry development module to execute:
(a) performing the wet development on the metal-containing resist in the wet development module to partially remove one of the first region and the second region in a thickness direction of the one of the first region and the second region; and
(b) performing dry development on the metal-containing resist in the dry development module to remove a remaining portion of the one of the first region and the second region.

16. The substrate processing system of claim 15, further comprising a first heating module,
wherein the controller is configured to further execute (c) heating the substrate in the first heating module before (a).

17. The substrate processing system of claim 16, further comprising a second heating module,
wherein the controller is configured to further execute (d) heating the substrate in the second heating module between (a) and (b), and
wherein a temperature of the substrate in (d) is higher than a temperature of the substrate in (c).

18. The substrate processing system of claim 15, wherein the dry development module includes a heating mechanism configured to heat the substrate,
wherein the controller is configured to further execute:
(c) heating the substrate by the heating mechanism in the dry development module before (a); and
(d) heating the substrate by the heating mechanism in the dry development module between (a) and (b), and
wherein a temperature of the substrate in (d) is higher than a temperature of the substrate in (c).

19. The substrate processing system of claim 16, wherein the dry development module includes a heating mechanism configured to heat the substrate,
wherein the controller is configured to further execute (d) heating the substrate by the heating mechanism in the dry development module between (a) and (b), and
wherein a temperature of the substrate in (d) is higher than a temperature of the substrate in (c).

20. A substrate processing system, comprising:
a first dry development module configured to perform dry development on a metal-containing resist of a substrate, the metal-containing resist including an exposed first region and an unexposed second region;
a second dry development module configured to perform dry development on the metal-containing resist, and having a heating mechanism configured to heat the substrate;
a transfer module configured to transfer the substrate to the first dry development module and the second dry development module; and
a controller,
wherein the controller is configured to control the transfer module, the first dry development module, and the second dry development module to execute:
(a) performing dry development on the metal-containing resist in the first dry development module or the second dry development module to partially remove one of the first region and the second region in a thickness direction of the one of the first region and the second region;
(b) heating the substrate by the heating mechanism in the second dry development module after (a); and
(c) performing dry development on the metal-containing resist in the second dry development module to remove a remaining portion of the one of the first region and the second region.

21. The substrate processing system of claim 20, wherein (a) includes performing dry development on the metal-containing resist in the second dry development module.

22. The substrate processing system of claim 21, wherein the controller is configured to further execute (d) heating the substrate in the second dry development module before (a), and
wherein a temperature of the substrate in (b) is higher than a temperature of the substrate in (d).
